(19) United States
(12) Patent Application Publication
(10) Pub. No.: US 2009/0110626 A1
(43) Pub. Date: Apr. 30, 2009

(54) Low Pressure Method of Annealing Diamonds

(76) Inventors: Russell J. Hemley, Washington, DC (US); Ho-Kwang Mao, Washington, DC (US); Chih-Shiue Yan, Washington, DC (US); Yufei Meng, Washington, DC (US)

Correspondence Address: MORGAN LEWIS & BOCKIUS LLP, 1111 PENNSYLVANIA AVENUE NW, WASHINGTON, DC, 20004, US

(21) Appl. No.: 12/244,053

(22) Filed: Oct. 2, 2008

Related U.S. Application Data
(60) Provisional application No. 60/960,520, filed on Oct. 2, 2007.

(51) Int. Cl. B01J 3/06; A62D 3/10; C30B 15/14

(52) U.S. Cl. 423/446; 204/157.43; 117/3

(57) ABSTRACT

The present invention relates to method of improving the optical properties of diamond at low pressures and more specifically to a method of producing a CVD diamond of a desired optical quality which includes growing CVD diamond and raising the temperature of the CVD diamond from about 1400° C. to about 2200° C. at a pressure of from about 1 to about 760 torr outside the diamond stability field in a reducing atmosphere for a time period of from about 5 seconds to about 3 hours.

This application claims the benefit of U.S. Provisional Application No. 60/960,520, filed on Oct. 2, 2007, which is hereby incorporated by reference in its entirety.

### STATEMENT OF GOVERNMENT INTEREST

This invention was made with U.S. government support under grant number NSF EAR-0550040 from the National Science Foundation. The U.S. government has certain rights in the invention.

### BACKGROUND OF THE INVENTION

1. Field of the Invention

The present invention relates generally to annealing diamond, and more particularly to annealing single crystal CVD diamond at low pressures, i.e., at pressures much lower than previously used for annealing single crystal CVD diamond, including pressures of around one atmosphere or below. The invention is useful for improving the optical properties of diamonds, and is particularly useful in the production of single crystal CVD diamond of high optical quality at a rapid growth rate.

2. Discussion of the Related Art

Chemical vapor deposition growth of diamonds is achieved by imparting energy into gas-phase carbon containing precursor molecules. For example, microwave energy can be used to create plasma that deposits carbon upon a seed diamond to form a diamond. Up until recent years, all CVD techniques for growing diamond resulted in polycrystalline diamond or very thin layers of single crystal diamond. Three of the inventors of this application (i.e., Drs. Hemley, Mao and Yan) have developed a microwave plasma CVD techniques to grow large single crystal CVD, these techniques disclosed in patent application Ser. No. 10/288,499, filed on Nov. 6, 2002, now U.S. Pat. No. 6,858,078; patent application Ser. No. 11/438,260, filed on May 23, 2006; patent application Ser. No. 11/599,361, filed on Nov. 15, 2006, all of which are hereby incorporated by reference.

The present inventors' microwave plasma CVD technique can grow a single crystal diamond on a seed diamond, such as a yellow type Ib HPHT synthetic diamond, at rates up to and exceeding 150 micrometers an hour. The color of the diamonds produced by the present inventors' microwave plasma CVD technique depends on the temperature at which the diamond is grown. More particularly, when diamond is grown within a certain temperature range, which is dependent upon the mixture of gases in the plasma, a colorless diamond can be produced. However, diamonds produced at temperatures outside of the certain range can be yellow or brown in color.

The lightening of the brown color in brown natural diamonds, as well as a decrease in impurities by high pressure high temperature annealing has been reported by I. M. Reinitz et al. Gems & Gemology 36, 128-137 (2000).

The majority of natural diamonds have a brown color, which makes them less attractive as gemstones. (See e.g., Fritsch E., in: G. E. Harlow (Ed.) (1998) The Nature of Diamonds, Cambridge University Press, UK, 23-47 HPHT annealing has been the current commercial process for enhancing the color of natural brown diamonds since 1999, and this process requires temperatures in the range of 1800-2500° C. and high pressure in the range of 5 GPA to prevent diamond from graphitizing. See, e.g., A. T. Collins, H. Kanda, and H. Kitawaki, “Color change produced in natural brown diamonds by high-pressure, high-temperature treatment”, Diamond Relat. Mater. 9, 113-122 (2000); Alan T. Collins, Alex Connor, Cheng-Han Ly, Abdulla Shareef, Paul M. Spear, “High-temperature annealing of optical centers in type-I diamond”, J. Appl. Phys. 97, 083517 (2005); D. Fisher and R. A. Spits, Gems. Gemol. 36, 42 (2000).) The reduction of the brown color noted in natural diamonds with low nitrogen concentration is attributed to the annealing of plastic deformation. (See e.g., L. S. Hounsome, et al. “Orgin of brown coloration in diamond”, Physical Review B 73, 125203 (2006)). In nitrogen-containing diamonds the vacancy released from the dislocations during this annealing are trapped to form N-V-N center in the neutral charge state H3 band gives the diamonds a yellow-green color.

A fraction of natural brown diamonds had ever been turned to colorless or near colorless by high temperature treatment (>700° C.) (See e.g., Ming-sheng Peng et al. “Studies on color enhancement of diamond”, Hunan Geology Supp. 17-21 (1992)).

The following defects are observed in nitrogen-doped SC-CVD diamonds: substitutional nitrogen (Ns⁰ and Ns⁺), nitrogen-vacancy complex (NV⁻ and NV⁰), nitrogen-vacancy-hydrogen (NVH⁻), vacancy-hydrogen complex, silicon-vacancy complex, and non-diamond carbon.

U.S. Pat. No. 7,172,655 is directed to a method of producing single crystal CVD diamond of a desired color, including, for example, colors in the pink-green range.

Three of the present inventors have discovered HPHT annealing of a single crystal yellow or brown CVD diamond at a temperature of 1800-2900° C. and at a pressure of 5-7 GPa for about 1-60 minutes using a reaction vessel in a conventional high pressure high temperature apparatus so as to transform some single crystal brown CVD diamonds into transparent colorless single crystal diamond (see U.S. application Ser. No. 10/889,171, filed Jul. 13, 2004). More particularly, Drs. Hemley, Mao and Yan discovered that a single crystal yellow or light brown CVD diamond grown with high growth rate at a temperature of about 1400-1460° C., in an atmosphere containing 4-5% N₂/CH₄ ratio, and at a pressure at least 4.0 GPa outside of the diamond stability field can be annealed to become a colorless single crystal diamond. Raman and PL spectra of such an annealed CVD diamond demonstrated the disappearance of hydrogenated amorphous carbon and a significant decrease in N-V impurities in such a colorless single crystal diamond. These changes appeared to be similar to the report by I. M. Reinitz et al. of transparency enhancement produced by HPHT annealing of brown natural diamond.

The high pressures involved in the above-described method result can result in high costs. Accordingly, it is desirable to develop a low pressure method of annealing diamond to improve certain characteristics of diamond, including optical properties. It is also desirable to develop a low pressure annealing method that can be used for different types of diamonds, including, but not limited to, CVD diamonds (single and polycrystalline diamonds), HPHT diamonds, and natural diamonds.

An object of the present invention is to enhance the optical properties of diamond. Another object of the present invention is to lighten or remove the color from a diamond. Yet another object of the present invention is to improve the qualities of any type of diamond, including, but not limited to single-crystal and polycrystalline CVD diamonds, HPHT diamond and natural diamonds. One additional object of the invention is to achieve the aforementioned objectives through a method that operates at a low pressure. Other objects will also be apparent from the following description of the invention.

### SUMMARY OF THE INVENTION

Broadly stated, the present invention is directed to methods of annealing diamond, or improving its optical properties, that substantially obviates one or more problems due to limitations and disadvantages of the related art.

Additional features and advantages of the invention will be set forth in the description which follows, and will be apparent from the description, or may be learned from practice of the invention. The objectives and other advantages of the invention will be realized and attained by the structure particularly pointed out in the written description and claims.

To achieve these objects and other advantages and in accordance with the purpose of the invention, as embodied and broadly described, a method to improve the optical quality of diamond includes raising the temperature of the diamond from about 1000° C. to about 2200° C. and controlling the pressure of the diamond to about 5 atmosphere or less outside the diamond stability field. The above conditions are controlled in a reducing atmosphere and the diamond is held within a heat sinking holder which makes thermal contact with a side surface of the diamond adjacent to the edge of the diamond.

Also disclosed is a method of producing a CVD diamond, which includes controlling the temperature of a growth surface of the diamond such that the temperature of the growing diamond crystals is in the range of 900-1400° C. and the diamond is mounted in a heat sink holder made of a material that has a high melting point and high thermal conductivity to minimize temperature gradients across the growth surface of the diamond; growing diamond by microwave plasma chemical vapor deposition on the growth surface of a diamond in a deposition chamber having an atmosphere greater than 150 torr, wherein the atmosphere comprises from about 8% to in excess of about 30% CH₄ per unit of H₂; removing the grown single-crystal diamond from the chamber while still in the heat sink holder; and raising the temperature of the CVD diamond from about 1400° C. to about 2200° C. at a pressure of from about 1 to about 760 torr outside the diamond stability field in a reducing atmosphere for a time period of from about 5 seconds to 3 hours. The CVD diamond produced by the above method can be single crystal CVD diamond.

It is to be understood that both the foregoing general description and the following detailed description of the present invention are exemplary and explanatory and are intended to provide further explanation of the invention as claimed.

### BRIEF DESCRIPTION OF THE FIGURES

FIG. 1 provides a graph of growth rate vs. color for single crystal CVD diamonds, some of which were annealed via the disclosed low pressure, high temperature method to improve optical quality.

FIG. 2 provides photographs of CVD diamond before and after low pressure annealing treatment.

FIG. 3 shows UV-VIS absorption spectra of diamond before and after annealing.

FIG. 4 shows photoluminescence spectra of brown diamond before and after annealing.

FIGS. 5a and 5b show infrared absorption spectra of diamond before and after annealing.

### DETAILED DESCRIPTION OF THE INVENTION

Reference will now be made in detail to the preferred embodiments of the present invention.

The methods of the invention are essentially twofold: the first is a low pressure method to anneal diamond, or improve its optical properties, and the second is a two-step process of rapidly producing diamonds of high optical quality by a) growing single crystal diamond, preferably single crystal diamond, and preferably by microwave plasma chemical vapor deposition, and then b) performing the low pressure method to anneal, or improve the optical quality of, the grown diamond. The latter method is particularly useful, insofar as it provides a means of improving the quality of CVD diamonds that have been rapidly grown at rates at which it is common to produce off-color diamonds (e.g., brown diamonds).

The term “annealing” as used when referring to the methods of this application would be understood to improve certain properties in diamond including, but not limited to, reducing residual stresses, eliminating defects, and lightening or removing color. For example, annealing is understood to improve the optical quality of diamond.

The high temperature, low pressure method of annealing diamond (hereinafter, also known as “HT” annealing or the “HT” method) can be performed on any type of diamond, including, but not limited to, single crystal CVD diamond, polycrystalline CVD diamond, HPHT diamond and natural diamond. In a preferred embodiment, the method of annealing, or improving the optical quality of, diamond is performed using CVD diamond. In a more preferred embodiment, the method is performed using single crystal CVD diamond.

The heating sources used to raise the temperature of the diamond in the low pressure, high temperature annealing methods include, but are not limited to, microwave, hot filament, furnace, or oven heating sources.

The low pressure, high temperature annealing treatment can enhance the color of the diamonds by at least 3 grades. For example, brown K grade color subjected to the annealing treatment can be enhanced to a G grade. Brown G grade color can be upgraded via said annealing treatment to an E-F grade, with pink color in transmittance near 550 n. Such improvements in color demonstrate that the high temperature, low pressure methods are comparable in results to those achieved using the high temperature, high pressure annealing methods disclosed in, for example, U.S. application Ser. No. 10/889,171.

Color is estimated by normalized transmittance of 100% at 800 nm and assigned the values E, F, G, H, I, J, K, L, and M in accordance with a transmittance of 80, 70, 60, 50, 40, 30, 20, 10, 0% at 400 nm, respectively. As discussed, the low pressure, high temperature annealing treatment enhances the color by three grades.

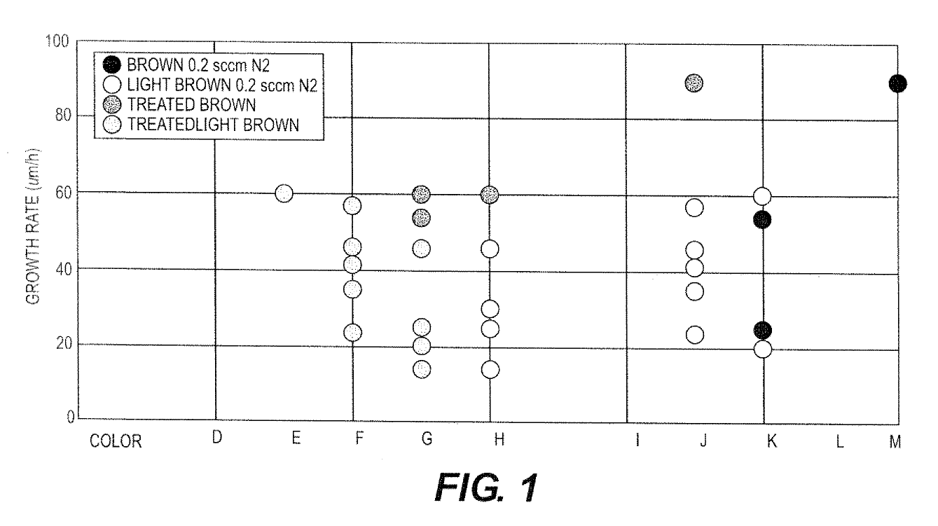

Referring more specifically the drawings, FIG. 1 shows a graph of growth rate vs. color for single crystal CVD diamonds, some of which were annealed via the disclosed low pressure high temperature method to improve optical quality. The diamonds shown in the graph are high quality single crystal CVD diamonds possessing nitrogen impurities from below 10 ppb to over 400 ppm as a type I or type II diamond. The diamonds were over 18 mm thick (15 carats) and were produced by the inventors using the very high growth rate process disclosed in, for example, U.S. application Ser. Nos. 11/438,260 and 11/599,361. The diamonds were annealed at temperatures of from about 1400° C. to about 2200° C. for a time period of from about 5 seconds to about 3 hours. The diamonds were maintained in a reducing atmosphere of about 1 torr to about 5 atmospheres, which is understood to prevent significant graphitization of the diamond. Hydrogen was used to maintain the reducing atmosphere in most of the tests. The diamonds, which were heated via microwave plasma CVD, were placed inside a molybdenum holder, an example of which is disclosed, for example, in U.S. Pat. No. 6,858,078. The diamond in the holder was then surrounded with graphite powder in order to ensure a uniform temperature distribution and to prevent the microwave plasma from etching and heating the diamond to the extent that it cracks.

The single crystal CVD diamonds treated by the low pressure, high temperature annealing process discussed above have at least one of the following characteristics:
1. Dark diamonds will change to colorless or near colorless with a fancy color, such as a tinted pink, red or purple.
2. The PL intensity of the original nitrogen-vacancy impurity N-V center at 575 nm and 637 nm excited by a laser will increase or decrease, and there will be an H3 center (nitrogen-vacancy complex) at 503 nm that did not exit until the annealing step.
3. The a-C:H infrared absorption broad band at 2930 cm⁻¹ is annealed to well-resolved {111} and {100} C-H stretching vibrational peaks, mainly at 2810 cm⁻¹, 2870 cm⁻¹ and 2900 cm⁻¹. The hydrogen induced electronic transition absorption at about 7357 cm⁻¹. 6856 cm⁻¹ and 6429 cm⁻¹ has decreased greatly.
4. Under a polarized microscope, a lower optical birefringence is indicative of lower strain compared to the original diamond.
5. Vicker's hardness tests show decreased fracture lines, which are indicative of higher toughness.

Diamonds with low and high nitrogen impurities that have been annealed in accordance with the high temperature, low pressure annealing method discussed above, are suited for uses, including, but not limited to, optics, mechanical and electronic applications, gemstones, laser windows and gain media, heat sinks, quantum computing, semiconductors, and wear resistant applications.

As can be seen in FIG. 1, brown diamonds which were grown via microwave plasma CVD using 0.2 sccm N₂ in 50 sccm CH₄ and light brown diamonds grown via microwave plasma CVD (MPCVD) using 0.1 sccm N₂ in 50 sccm CH₄ had color in the ranges of K-M and H-K range, respectively. After low pressure, high temperature treatment, the diamonds had color in the following ranges: brown diamonds (G-J) and light brown diamonds (E-G). This shows that a color enhancement of approximately 3 color grades is achieved by subjecting the diamonds to the low pressure, high temperature annealing methods of the invention.

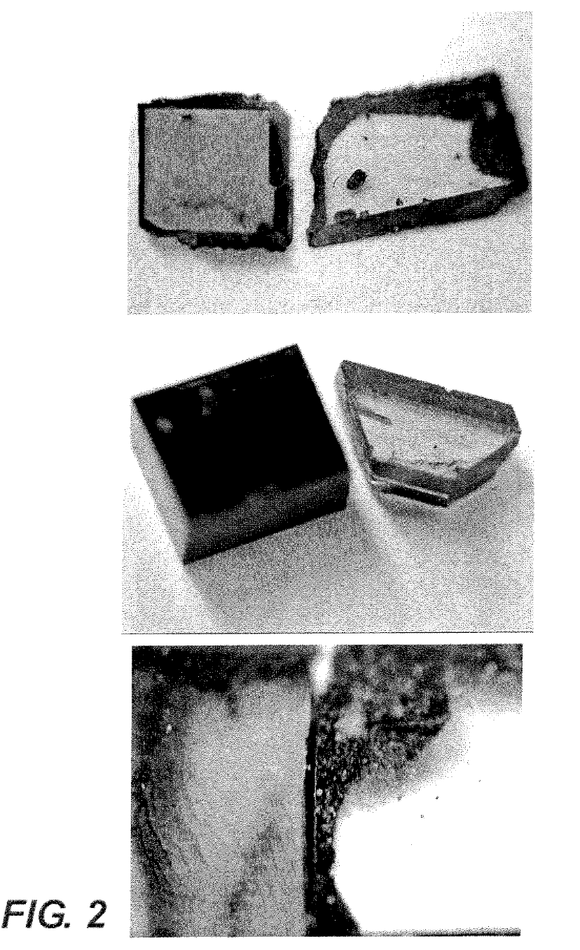

FIG. 2 shows photographs of MPCVD diamonds before and after low pressure, high temperature annealing treatment. In the three separate photographs, the diamond on the left side has not been treated with the low pressure, high temperature annealing process. The diamonds on the right side have been treated with the low pressure, high temperature annealing process. The difference in transparence between the diamonds before treatment and after treatment is readily apparent from the photographs.

### EXAMPLES

Various SC-CVD diamonds produced by the Carnegie Institution at a very high growth rate process possess the following properties: (1) nitrogen impurities from below 10 ppb to over 400 ppm, as determined from secondary ion mass spectrometer (SIMS) measurements, (2) color from colorless to near-colorless to brown as type I and type II diamond, an (3) size up to over 18 mm thick (or 15 carat). Those diamonds produced with intentionally added nitrogen at temperatures from 600 to 1400° C. have been shown to enhance growth rate and promote {100} faceted growth and prevent the formation of twins and polycrystalline diamond. The intensity of brown color depends most on temperature and the concentration of nitrogen in gas. Near-colorless to brown SC-CVD diamond could be produced at nitrogen concentrations below 2% N₂/CH₄, brown to dark brown diamonds with obvious non-diamond carbon band near 1500 cm⁻¹ in Raman excited by 514 nm laser spectra could be produced at 20% to 1000% N₂/CH₄.

Brown diamonds were annealed at high temperature from 1400 over 2200° C. at a time from couple hours to below 1 minute at a hydrogen gas pressure of 200 torr in a microwave plasma CVD chamber. The diamonds were heated via microwave plasma CVD method and were placed inside a molybdenum holder surrounded by graphite powder in order to even out the temperature distribution and prevent microwave and plasma from locally etching and heating up the diamond, which could result in thermal cracking.

It must be noted that the brown tough SC-CVD diamonds should be of high quality single crystal diamond to prevent significant graphitization and cracks resulting from the following conditions: high temperature (e.g., over 1600° C.), low pressure outside the diamond stability pressure, and under energetic hydrogen plasma etch. Single crystal CVD diamonds after high temperature treatment at 1400-2200° C. show dramatically enhanced optical, electronic and mechanical characteristics.

Forty more type-II SC-CVD diamond plates prepared by HT annealing with nitrogen impurity levels below 10 ppm, at thicknesses of 0.2 to 3 mm, were characterized as follows:

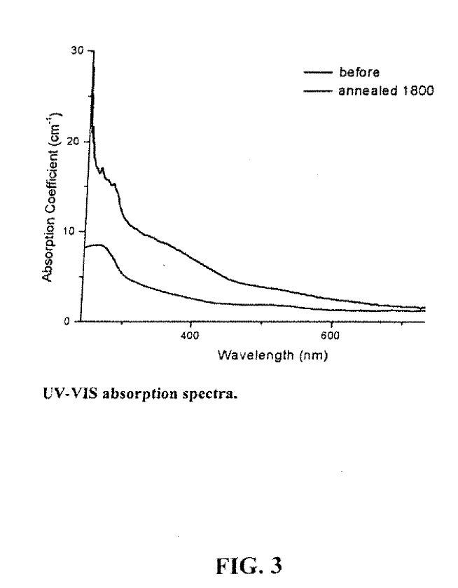

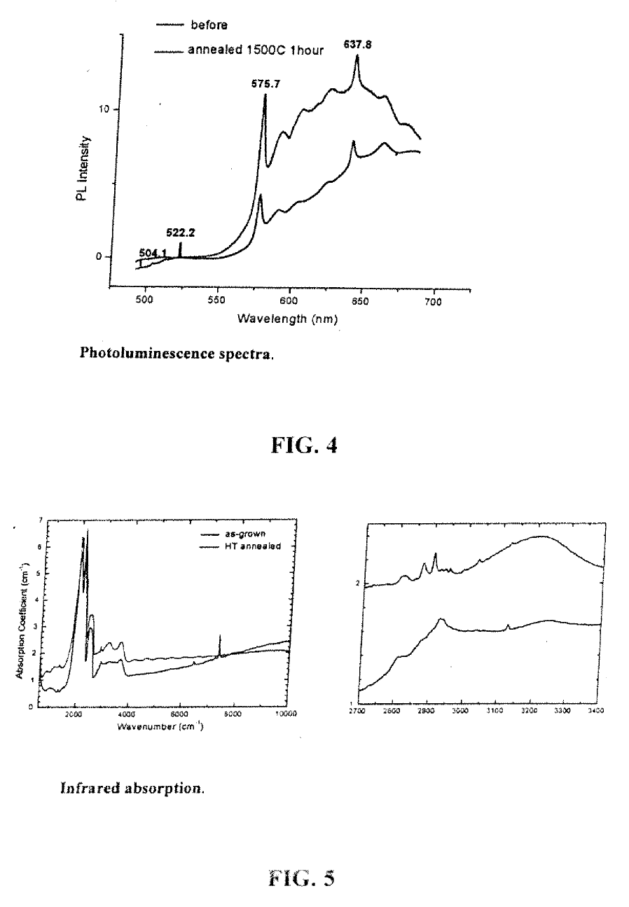

I. UV-VIS absorption: After HT treatment, the brown diamond changed to colorless or near colorless with fancy color, such as tinted pink, red, purple or orange-pink. As seen in the UV-VIS absorption spectra in FIG. 3, dark diamonds usually have three broad absorption bands in the visible region: 270 nm substitutional nitrogen absorption, 370 and 550 nm, broad bands that decrease after HT annealing. Similar color enhancements have been reported in HPHT annealing. The color grade is enhanced an average of 3 grades, such as from J color to G color, the grades evaluated from absorption spectra. The dramatic color enhancement of CVD diamond was not observed for diamond annealed under atmospheric pressure when temperatures were below 1500° C.

II. Photoluminescence: The photoluminescence (PL) spectra of brown CVD diamond, as seen in FIG. 4, shows that the intensity of original nitrogen-vacancy impurity [N-V]⁰ and [N-V]⁻ center at 575 nm and 637 nm excited by laser still exists, and the H3 center (nitrogen-vacancy complex) at 503 nm that did not exist before HT annealing will start to appear. There are two stages to N-V centers as HT annealing develops. After annealing is performed at lower temperatures or short timeframes, the PL intensity of [N-V]⁰ (575 nm) and [N-V]⁻ (637 nm) centers has increased by 1 to 5 times, which results in strong orange fluorescence by 488 nm excitation. Before annealing, the as-grown brown diamonds show dark red fluorescence. The orange hue of the HT annealed CVD diamond is thought to come from this orange fluorescence. At higher temperature or for long annealing times, the PL intensity of the [N-V]⁰ and [N-V]⁻ centers decreased. Unlike with HPHT treatment, the N-V center related to quantum computer applications will obviously decrease or disappear and will be dominated by strong H3 center in PL spectra. The trend is that the portion of the [N-V]⁻ center (637 nm) gets lower. This may imply that the content of electron centers decreases, as uncoupled electrons mainly from the [N-V]⁻ center become coupled to form 575 and H3 centers, thus relating to color enhancement.

III. Infrared absorption: Infrared absorption spectra reveal hydrogen related vibrational and electronic structural transformations upon HT annealing. FIG. 5 shows the C-H stretching vibrational band in the range at 2800-3200 cm⁻¹. The broad band at 2930 cm⁻¹ attributed to hydrogenated amorphous carbon (a-C:H) is observed in the brown CVD diamond. This intensity correlates with the brown color of the diamond and its high toughness. The a-C:H peak was HT annealed to various well-resolved C-H stretching bands at 2810 cm⁻¹ (sp³-hybridized bonds on {111}), 2870 (sp³ —CH₃), and 2900 cm⁻¹ (sp³-hybridized bonds on {100}), 2925 (sp³ —CH₂—), 2937 and 2948 cm⁻¹, 3032 and 3053 cm⁻¹ (sp²-hybridized bonds). The {111} surfaces within the CVD implies the relatively open a-C:H structure with dangling bond in the as-grown brown {100} CVD diamond transformed by annealing to a locally denser structure (2) with enhanced color. Possible mechanisms of color enhancement have been described based on the observation of the C-H stretching of HPHT annealing CVD diamond. In the electronic transition region (FIG. 5b), the main absorption at 7357 cm⁻¹ (0.913 eV, hydrogen induced electronic transition), 7220 cm⁻¹, 6856 and 6429 cm⁻¹ and minor absorption at 8761 and 5567 cm⁻¹ have greatly decreased or vanished. Moreover, the continuous increasing absorption from 5000 to 10000 cm⁻¹ of the near infrared region decreased. The above HT annealing effects are similar to that of HPHT annealing. An exception is that HT and raw CVD diamonds have the 124 cm⁻¹ peak (H involving one C) and 7357 cm⁻¹, 7220 cm⁻¹, 6856 and 6429 cm⁻¹, which HPHT diamonds do not have. And HT diamonds do not have 3107 cm⁻¹ (sp² —CH═CH—) related to gray color, which exists in HPHT annealing samples as well as 2972 (sp² —CH₂— (28)) and 2991 cm⁻¹. Another possible difference is the high-pressure induced sp³ C—H bond shift to a higher wave number by 3-15 cm⁻¹ as 2820 cm⁻¹, 2873 cm⁻¹ and 2905 cm⁻¹ in HPHT annealed samples.

IV. Birefringence: Under the microscope with crossed polarizers, lower optical birefringence was observed in HT annealed diamonds, which is indicative of lower strain compared to non-annealed, original diamond, such that color order turns from yellow to gray, and two crossed directions strain becomes one direction, further suggesting less stress.

Characterization of CVD diamond before and after HT annealing, as compared with HPHT annealing, reveals the annealing mechanism and brown color origin as well as the pink color. Based on the UV-VIS, PL and SR-FTIR spectra, one can deduce a mechanism underlying the high temperature annealing of CVD brown diamond. As the annealing temperature increases, PL and SR-FTIR spectra reveal three important periods for color change. At the first stage, when temperature reaches 700° C., vacancies become mobile and more NV centers form because vacancies are trapped at Ns centers. While it is considered theory, it is believed that this is the reason why the PL intensity of NV⁰ and NV⁻ centers increases after lower temperature or short time annealing. The brown color remains unreduced until 1400. Secondly, on heating to 1400° C., the color starts to change. While it is considered theory, it appears that this is because hydrogen becomes mobile at this temperature. It has been found that some of the hydrogen on internal grain boundaries or in intergranular material became mobile upon annealing polycrystalline CVD diamond at 1700K (1400° C.). See D. F. Talbot-Ponsonby, M. E. Newton, J. M. Baker, G. A. Scarsbrook, R. S. Sussmann and A. J. whitehead. Phys. Rev. B 57, 2302-2309 (1998). Accordingly, in the FTIR spectra, the a-C:H decreases, and hydrogen forms C—H bonds on {100} and {111}. First principles modeling studies show that hydrogen could passivate the optical activity of the {111} vacancy disks. See L. S. Hounsome, et al. “Origin of brown coloration in diamond”, Physical Review B 73, 125203 (2006). The 270 and 370 nm absorption decreases, while the 550 nm absorption increases or remains unchanged, which results in a pinkish brown, orange brown or purple color. One can observe the mirrored symmetrical relationship of the 550 nm absorption band with the 575 and 637 nm NV center emission bands. This appears to prove that the 550 nm absorption is caused by NV centers. Accordingly, the pink hue of CVD diamond originates from NV centers, which are stable.

The best color enhancement is observed at a temperature higher than 1700° C., where the brown color turns into pink, colorless or near colorless, or a tinted pink/green. One possible reason is that vacancies are more easily trapped by hydrogen than nitrogen at temperatures where more hydrogen atoms are motivated, and at the same time the stable NV centers are annealed out since Ns is also motivated to form aggregate H3 at this temperature. Another possible change is the loss of hydrogen. One can observe the lower intensity of C—H stretching vibration absorption even after higher temperature annealing (1800-2200° C.). This probably indicates the breaking of CH bonds.

There are three factors that correlate with the brown color of CVD diamond: nitrogen, vacancy and hydrogen. The intensity of brown color in as-grown CVD diamond depends on the concentration of nitrogen in gas. The brown color also deepens while the original PL intensity of [N-V]⁰ (575 nm) and [N-V]⁻ (637 nm) centers increase in as-grown CVD diamond. When diamond is annealed to near colorless or colorless, NV centers are reduced or disappear. The a-C:H peak in brown CVD diamond is annealed at high temperature, low pressure to various well-resolved C-H stretching bands and hydrogen induced electronic transition absorption decrease. The a-C:H peak and hydrogen induced electronic transition absorption is very low or absent in colorless as-grown CVD diamond.

Compared to HPHT annealing of CVD diamond, the high temperature, low pressure method is much less expensive. It is also flexible as it relates to the size of samples because thin plates will crack during HPHT treatment and large samples over 10 cm cube cannot fit in HPHT press. Besides color enhancement, the high temperature low pressure annealing process can produce diamonds with low and high nitrogen impurities. A potential application for such diamonds is in a quantum computer. Pink diamond is thought to be the promising host for quantum computer. The NV⁻ spins provide much of what is needed for a practical cubit and have been widely studied in the context of quantum computing. Based on the absorption and emission, it is concluded that the pink color of CVD diamonds originates from the N-V centers. The pink CVD diamond produced by high temperature, low pressure annealing contains an increased intensity of NV centers compared to as-grown CVD diamond, whereas the HPHT process will anneal such centers out. It is thus possible to control the intensity of NV centers through the high temperature, low pressure annealing process. Therefore, the high temperature, low pressure annealed pink CVD diamond should be a promising material for a quantum computer in the future.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. A method to improve the optical properties of diamond comprising:
(i) raising the temperature of the diamond from about 1000° C. to about 2200° C. and
(ii) controlling the pressure of the diamond to about 5 atmosphere or less outside the diamond stability field,
wherein the pressure is controlled in a reducing atmosphere, and
wherein the diamond is held within a heat sinking holder which makes thermal contact with a side surface of the diamond adjacent to the edge of the diamond.

2. The method of claim 1, further comprising surrounding the diamond in the heat sinking holder with a powder having melting point higher than 2500° C.

3. The method of claim 2, wherein the powder comprises graphite.

4. The method of claim 1, wherein the diamond is CVD diamond.

5. The method of claim 4, wherein the CVD diamond is single crystal CVD diamond.

6. The method of claim 1, wherein the temperature of the diamond is raised from about 1400° C. to about 2200° C.

7. The method of claim 1, wherein the pressure is maintained between about 1 torr and about 760 torr.

8. The method of claim 1, wherein the temperature of the diamond is raised using a source from the group consisting of the following: microwave, hot filament, furnace, torch and an oven source.

9. The method of claim 8, wherein the temperature of the diamond is raised using a microwave source.

10. The method of claim 5, wherein the CVD diamond is a single crystal coating upon another material.

11. The method of claim 5, wherein the single crystal CVD diamond initially has a brown color and becomes colorless.

12. The method of claim 2, wherein the heat sinking holder is comprised of molybdenum.

13. A method of producing CVD diamond of a desired optical quality comprising:
i) controlling the temperature of a growth surface of the diamond such that the temperature of the growing diamond crystals is in the range of 900-1400° C. and the diamond is mounted in a heat sink holder made of a material that has a high melting point and high thermal conductivity to minimize temperature gradients across the growth surface of the diamond;
ii) growing diamond by microwave plasma chemical vapor deposition on the growth surface of a diamond in a deposition chamber having an atmosphere greater than 150 torr, wherein the atmosphere comprises from about 8% to in excess of about 30% CH₄ per unit of H₂, and comprises from about below 2% to in excess of about 1000% N₂ per unit of CH₄.
iii) removing the grown CVD diamond from the chamber while still in the heat sink holder;
iv) raising the temperature of the CVD diamond from about 1400° C. to about 2200° C. at a pressure of from about 1 to about 760 torr outside the diamond stability field in a reducing atmosphere for a time period of from about 5 seconds to 3 hours.

14. The method of claim 13, further comprising in step iv.) surrounding the diamond in the heat sinking holder with a powder having melting point higher than 2500° C. prior to raising the temperature of the CVD diamond from about 1400° C. to about 2200° C.

15. A method of producing a single crystal CVD diamond of a desired optical quality comprising:
i) controlling the temperature of a growth surface of the diamond such that the temperature of the growing diamond crystals is in the range of 900-1400° C. and the diamond is mounted in a heat sink holder made of a material that has a high melting point and high thermal conductivity to minimize temperature gradients across the growth surface of the diamond;
ii) growing single-crystal diamond by microwave plasma chemical vapor deposition on the growth surface of a diamond in a deposition chamber having an atmosphere greater than 150 torr, wherein the atmosphere comprises from about 8% to in excess of about 30% CH₄ per unit of H₂, and comprises from about below 2% to in excess of about 1000% N₂ per unit of CH₄;
iii) removing the grown single-crystal diamond from the chamber;
iv) improving the optical quality of the diamond via the method of claim 6.

16. A method of producing a CVD diamond comprising:
i) growing CVD diamond
ii) raising the temperature of the CVD diamond from about 1400° C. to about 2200° C. at a pressure of from about 1 to about 760 torr outside the diamond stability field in a reducing atmosphere for a time period of from about 5 seconds to about 3 hours.

17. A single crystal CVD diamond produced by the method of claim 15.

18. A CVD diamond produced by the method of claim 16.

19. A single crystal CVD diamond produced by the method of claim 15 with a color of F or below.

20. A single crystal diamond produced by the method of claim 15 wherein, as a result of step iv.), the N-V center will increase or decrease or disappear or the photoluminescence spectra will be dominated by a strong H3 center.

21. A single crystal diamond produced by the method of claim 16 wherein, as a result of step ii.), the N-V center will increase or decrease or disappear or will be dominated by a strong H3 center in the photoluminescence spectra.

22. A single crystal diamond produced by the method of claim 15, wherein the diamond has infrared absorption peaks at about 3124, 7357, 7220, 6856 and 6429 cm⁻¹.

23. A single crystal diamond produced by the method of claim 16, wherein the diamond has infrared absorption peaks at about 3124, 7357, 7220, 6856 and 6429 cm⁻¹.
